(19) United States
(12) Patent Application Publication
(10) Pub. No.: US 2026/0060098 A1
(43) Pub. Date: Feb. 26, 2026

(54) Semiconductor Device and Connecting Method

(71) Applicant: WASEDA UNIVERSITY, Tokyo (JP)

(72) Inventors: Kohei TATSUMI, Kitakyushu-shi, Fukuoka (JP); Keiko KOSHIBA, Tokyo (JP)

(21) Appl. No.: 19/104,701

(22) PCT Filed: May 15, 2023
(86) PCT No.: PCT/JP2023/018085

§ 371 Date: Feb. 18, 2025

(30) Foreign Application Priority Data
Aug. 30, 2022 (JP) 2022-137056

(51) Int. Cl. H01L 23/495; H01L 23/00

(52) U.S. Cl. CPC H01L 23/49513; H01L 24/27; H01L 24/28; H01L 24/32; H01L 2224/27442; H01L 2224/2746; H01L 2224/27848; H01L 2224/29082; H01L 2224/29124; H01L 2224/29155; H01L 2224/2916; H01L 2224/32245; H01L 2224/32501

(57) ABSTRACT

The purpose of this invention is to provide a semiconductor device that prevents defects in semiconductor elements caused by differences in thermal expansion and maintains low electrical resistance by directly or indirectly laminating an Fe—Ni alloy metal layer onto the front-surface or back-surface electrodes of the semiconductor element. In this invention, an Fe—Ni alloy metal layer is directly or indirectly applied on the surface electrodes of the semiconductor element, and the semiconductor element is connected to a conductor through the Fe—Ni alloy metal layer. Depending on the application, the Ni content of the Fe—Ni alloy metal layer is set within the range of 36% to 45% by weight, and the thickness of the Fe—Ni alloy metal layer is set within the range of 2 μm to 20 μm.

### TECHNICAL FIELD

The present invention relates to semiconductor devices and the like, in which the difference in thermal expansion of the objects to be connected is suppressed by an Fe—Ni alloy metal layer.

### BACKGROUND ART

The mounting of a semiconductor element fundamentally involves securing it to a substrate, establishing conductive connections to the electrode terminals, and ensuring their insulation protection. Semiconductors generate heat due to the current flowing through the circuit, which results in thermal expansion. On the other hand, the thermal expansion rates of metals and insulating resins connected to semiconductors are generally an order of magnitude higher compared to those of semiconductor materials. For example, the coefficient of thermal expansion (CTE) of silicon (Si) is approximately 2.6 ppm/K, whereas the thermal expansion rate of copper, widely used as a conductor in wiring and for substrates, is about 16.5 ppm/K. When Si semiconductor and copper, a conductive wiring material, are connected, the strain caused by the thermal expansion difference becomes larger in proportion to the temperature and the length of the connection. The stress on the semiconductor element and the connection materials due to this strain can cause damage to semiconductor devices due to thermal fatigue caused by temperature cycles. Various measures have been taken to address this issue, but a fundamental solution has not yet been achieved. This is particularly challenging for power devices, where large currents flow.

To address such issues, ceramic substrates with a thermal expansion coefficient close to that of Si semiconductors have been used, with copper wiring formed on these ceramic substrates. For example, in logic devices such as CPU elements, ceramic packages were widely used in the early stages, but high costs became a major issue. Currently, organic material substrates are used, and measures such as sealing resins and underfill agents are taken to suppress the strain due to thermal expansion differences. However, these have limited heat resistance. Therefore, in high-power devices, alumina and silicon nitride substrates, which have thermal expansion coefficients close to those of Si or SiC semiconductors, are still widely used.

In recent years, there has been significant progress in the practical use of compound semiconductors such as SiC semiconductors, which allow the devices themselves to operate at higher temperatures compared to Si semiconductors and also enable higher output densities. As a result, there is a demand for mounting technologies that can suppress the thermal expansion difference and allow operation at high temperatures.

Fe—Ni alloy metals (e.g., 42 alloy, which contains 42% by weight of Ni) are known as materials with low thermal expansion coefficients that are close to the thermal expansion coefficient of semiconductors. These materials are sometimes used in electronic component leads and lead frames. Lead frames are generally formed from copper, which has excellent conductivity, and are often connected to Si semiconductor chips or SiC semiconductor chips using solder or paste containing resin components. As a result, thermal stress caused by the thermal expansion difference between the Si or SiC semiconductors and copper wiring can lead to plastic deformation of the solder in solder connections, which may result in fatigue failure due to repeated cycles. In the case of paste-based connections, issues such as delamination at the paste material or interface may occur. To address these issues, lead frames themselves have been formed from 42 alloy, which has a thermal expansion coefficient closer to that of Si or SiC semiconductors. However, the use of Fe—Ni alloy metal remains limited due to its lower electrical conductivity and thermal conductivity compared to copper, as well as cost considerations.

As a technology utilizing Fe—Ni alloy metal, techniques disclosed in Patent Documents 2 to 4 are known. The technology shown in Patent Document 2 connects a first connection lead made of an iron-nickel alloy with a thermal expansion coefficient of (1 to 6)×10⁻⁶/K to a second connection lead made of copper, such as by welding, and fixes the tip of the first connection lead to an electrode pad using solder. This reduces the thermal stress applied to the electrode pad and minimizes the thermal stress caused by the thermal expansion difference between the electrode pad and the first connection lead, preventing cracks from forming in the solder or the silicon under the electrode pad. Additionally, by limiting the length of the first connection lead to less than 40% of the combined length of the first and second connection leads, it is possible to maintain low electrical resistance and reduce the cost of the connecting conductors.

The technology shown in Patent Document 3 is a semiconductor lead frame comprising a base material made of an iron-nickel alloy and a plating layer formed on the base material with a crystal grain size of 1 micron or less. By minimizing the crystal grain size when plating with tin on the base material made of the iron-nickel alloy (alloy 42), the growth of whiskers can be suppressed.

The technology shown in Patent Document 4 involves a low-expansion member made of an iron-based sheet material, with iron-nickel layers formed on both the upper and lower surface layers of the sheet material. While the sheet material has a high thermal expansion coefficient, the iron-nickel layers formed on the upper and lower surface layers have a low thermal expansion coefficient. As a result, the overall thermal expansion coefficient of the low-expansion member can be minimized, and since the sheet material has high thermal conductivity and the iron-nickel layers are thin, the low-expansion member has high thermal conductivity in its thickness direction.

### PRIOR ART DOCUMENTS

### Patent Documents

Patent Document 1: WO 2015/053356
Patent Document 2: JP 2012-38983 A
Patent Document 3: JP 2006-108666 A
Patent Document 4: JP 2004-103700 A

### SUMMARY OF INVENTION

### Problems to be Solved by the Invention

However, the technologies shown in Patent Documents 1 and 2 are not sufficient to address issues related to the thermal expansion difference between semiconductors and conductors. In particular, the technology shown in Patent Document 2, which uses an Fe—Ni alloy metal lead to alleviate stress, still faces the issue that, even when the length of the first connection lead is less than 40% of the total length of the first and second connection leads, the low electrical conductivity and thermal conductivity compared to copper, as well as cost concerns, are not fully addressed.

Additionally, even when using the technologies described in Patent Documents 3 and 4, the problems mentioned above cannot be fully resolved.

The present invention was made to solve these problems, and its purpose is to provide a semiconductor device that prevents defects in semiconductor elements caused by differences in thermal expansion by coating an Fe—Ni alloy metal layer directly or indirectly onto the front-surface electrode or back-surface electrode of a semiconductor element, while also achieving low electrical resistance..

### Solution to Problem

The semiconductor device according to the present invention is characterized in that an Fe—Ni alloy metal layer is directly or indirectly coated onto the front-surface electrode or back-surface electrode of a semiconductor element, and the semiconductor element is connected to a conductor, being an electrically conducting material, through the Fe—Ni alloy metal layer.

Thus, in the semiconductor device according to the present invention, an Fe—Ni alloy metal layer is directly or indirectly coated to the front-surface electrode or back-surface electrode of the semiconductor element, and the semiconductor element and the conductor are connected through the Fe—Ni alloy metal layer. As a result, stress caused by the thermal expansion difference between the semiconductor element and the conductor is alleviated, thereby preventing damage to the semiconductor element.

### BRIEF DESCRIPTION OF THE DRAWINGS

FIG. 1: A graph showing the composition dependence of the linear thermal expansion coefficient of the Fe—Ni alloy.
FIG. 2: A diagram illustrating the structure of the semiconductor device when a lead frame is used.
FIG. 3: A diagram showing the connecting area of the semiconductor chip in wire bonding.
FIG. 4: A diagram showing the structure of the semiconductor device in a flip-chip connection in the first embodiment.
FIG. 5: A diagram showing the structure of a flip-chip connection with Cu pillars in the first embodiment.
FIG. 6: A diagram illustrating the structure of the semiconductor device as a power device in the first embodiment.
FIG. 7: An example of the structure of a lead-frame-type power device in the first embodiment.
FIG. 8: An example of the structure of a power device using a Cu clip in the first embodiment.
FIG. 9: An example of the NMPB structure in the first embodiment.
FIG. 10: Measurement results showing the linear expansion coefficient of the Fe—Ni alloy metal layer after plating treatment at various heating temperatures in the first embodiment.

### DESCRIPTION OF EMBODIMENT

Below, the embodiment of the present invention is described. Throughout the present embodiment, the same reference signs are used for the same elements.

### First Embodiment of the Present Invention

The semiconductor device according to the present embodiment will be described with reference to FIGS. 1 to 9. The semiconductor device of the present embodiment has a connection structure where an Fe—Ni alloy metal layer is directly or indirectly coated onto the front-surface electrode or back-surface electrode of a semiconductor chip, and the semiconductor chip is connected to a conducting material through the Fe—Ni alloy metal layer. Note that, in the embodiment described hereafter, the Fe—Ni alloy metal layer refers to a metal layer that includes at least Fe—Ni alloy, and may also contain metals other than Fe—Ni.

The thermal expansion coefficient of Fe—Ni alloy metal can be controlled to a few ppm, which is close to the thermal expansion coefficient of Si or SiC semiconductors. FIG. 1 shows the composition dependence of the linear thermal expansion coefficient of Fe—Ni alloys. The horizontal axis represents the Ni composition, and the vertical axis represents the thermal expansion coefficient. As shown in the graph, the thermal expansion coefficient is smallest when the Ni composition is 36%, and the commonly used lead frame material has a Ni composition of 42%. In the semiconductor device according to the present embodiment, it is expected that a Ni weight percentage concentration in the range of 30% to 45% can be expected to effectively suppress the thermal expansion rate of the conductor, as shown in FIG. 1.

Next, the structure of the semiconductor device according to the present embodiment will be explained in detail. FIG. 2 shows the structure when a lead frame is used in the semiconductor device. FIG. 2(A) shows a typical semiconductor mounting structure using a lead frame, and FIG. 2(B) shows the first diagram of the connecting structure between the semiconductor element and the conductor when a lead frame is used in the present embodiment. FIG. 2(C) shows the second diagram of the connecting structure, and FIG. 2(D) shows the third diagram of the connecting structure when a lead frame is used in the present embodiment.

In FIG. 2, the Si or SiC semiconductor (hereinafter referred to as the semiconductor chip 2) is die-bonded to the die pad (island) 3a of the lead frame 3. The semiconductor chip 2 and the lead 3b of the lead frame 3 are connected by a wire 8 and encapsulated with resin 6. Generally, the semiconductor chip 2 is die-bonded to the die pad 3a of conductor using solder 7 or a paste containing resin components, and the lead frame 3 is often made of copper, which has excellent electrical conductivity. In this case, as mentioned above, thermal stress caused by the thermal expansion difference between the semiconductor chip 2 (Si or SiC) and the lead frame 3 (Cu) due to temperature cycling may cause the solder 7 to plastically deform, resulting in fatigue failure over repeated cycles, or lead to delamination at the interface of the paste materials. Therefore, even if the lead frame 3 itself were made of Fe-42%Ni material, which has a thermal expansion coefficient closer to that of the semiconductor, its use would be limited due to issues such as electrical conductivity, thermal conductivity, and material cost.

The issue in the connecting of the semiconductor chip 2 and the conductor 4 (corresponding to the die pad 3a in FIG. 2) is the interface problem between the semiconductor chip 2 and the conductor 4. Therefore, in the semiconductor device 1 according to the present embodiment, as shown in FIG. 2(B), it is useful to apply an Fe—Ni alloy metal layer 5 with a controlled thermal expansion coefficient on the surface of the die pad 3a made of copper. Specifically, the Fe—Ni alloy metal layer 5 is laminated onto the die pad 3a, and the Ti/Ni/Au film 2a of the semiconductor chip 2 is connected via the solder 7. By forming an Fe—Ni alloy metal layer 5 with a thermal expansion rate close to that of the semiconductor chip 2 on the die pad 3a, the stress load on the solder 7 caused by the thermal expansion of copper can be reduced.

FIG. 2(C) shows the structure when an Fe—Ni alloy metal layer 5 with relatively high strength and a thermal expansion coefficient close to that of Si or SiC semiconductor is applied to the back-surface (bottom side) of the semiconductor chip 2. In this case, the Fe—Ni alloy metal layer 5 is applied to the Ti/Ni/Au film 2a on the surface of the semiconductor chip 2, and it is connected to the conductor 4 via the solder 7.

FIG. 2(D) shows the structure when an Fe—Ni alloy metal layer 5 is applied to the back-surface (bottom side) of the semiconductor chip 2, and the Fe—Ni alloy metal layer 5 is formed as the connecting material. In this case, the semiconductor chip 2 and the conductor 4 are bonded using Fe—Ni alloy metal layer 5, with nanoscale Ni particles as a binder on the surface of the Ti/Ni/Au film 2a of the semiconductor chip 2.

In FIG. 2(B) to 2(D), the Ni weight percentage concentration of the Fe—Ni alloy metal layer 5 is expected to be effective in the range of 30% to 45%. The thickness is effective when it is 2 μm or more, and preferably 5 μm or more.

In addition, for the connecting using solder 7, as shown in FIG. 2(B) and 2(C), alternative connection technologies capable of supporting high-temperature operations have been developed in recent years. For example, in cases where high-strength and high-adhesion die-bonding materials such as Ag sintered materials, Ni sintered materials, or nickel micro-plating bonding are used, no breakage or delamination at the interface of the connecting materials occurs. However, this can increase stress on the semiconductor chip 2, potentially leading to defects such as current leakage due to cracks within the semiconductor chip 2. As a countermeasure, in the present embodiment, as shown in FIG. 2(D), a robust bond can be achieved by relaxing the stress on the semiconductor chip 2 by mixing nanoscale Ni particles with the Fe—Ni alloy metal layer 5 as a sintering material. Furthermore, it is also possible to form the Fe—Ni alloy metal layer 5 containing microscale Al particles. The presence of Al particles can help mitigate thermal stress caused by the thermal expansion difference (see, for example, Japanese Patent Application JP2020-35983).

When the Fe—Ni alloy metal layer 5 contains nano-sized Ni particles or micron-sized Al particles, the thermal expansion coefficient of the Fe—Ni alloy metal layer 5 is determined based on the composite rule, taking into account the thermal expansion coefficient of the Fe—Ni alloy particles, as shown in FIG. 1, along with the thermal expansion coefficients of the Ni and Al particles and their respective mixing ratios. Specifically, the portion containing Ni particles has a thermal expansion coefficient corresponding to Ni (100%), and the portion containing Al particles has a thermal expansion coefficient corresponding to Al (100%). The linear expansion coefficient is then determined by the thermal expansion coefficient derived from the composition of the Fe—Ni alloy and the volumetric ratios of these components. Therefore, it is desirable to adjust the composition ratios of the Fe—Ni alloy metal layer 5 so that its linear expansion coefficient approximates the thermal expansion coefficient of Si or SiC semiconductors. The nanoscale Ni particles are preferably in the range of 10 nm to 200 nm. Additionally, nanoscale particles such as Ag or Cu particles, which have similar sizes and volume ratios to those of Ni particles, may also be used. Moreover, the effect of nanoscale Ni particles as a sintering material is preferable to be 15% or more by volume ratio, but considering the influence of the thermal expansion coefficient, it is desirable to keep it within the range of 60% or less.

Furthermore, for coating the Fe—Ni alloy metal layer 5, methods such as cladding, physical vapor deposition (PVD), plating, thermal spraying, or sintering can be used. As shown in FIG. 2(B), any of the above methods may be used to coat the Fe—Ni alloy metal layer 5 onto the conductor 4. As shown in FIG. 2(C), when it is applied to the back-surface side of the semiconductor chip 2, PVD or plating is used. In the case of FIG. 2(D), coating and connecting are performed by sintering nanoscale Ni.

In particular, when coating the Fe—Ni alloy metal layer 5 by plating, it may be necessary to optimize the composition and atomic rearrangement to achieve the thermal expansion coefficient of Fe—N as shown in FIG. 1. Specifically, to form the desired composition of Fe—Ni alloy metal layer 5 by plating, a heat treatment of about 200° C. to 350° C. is preferably performed after the plating process. Performing this heat treatment after plating forms a diffusion layer (for example, a layer where the metals diffuse at the interface by about 0.01 μm=10 nm or more), achieving a strong bond at the interface between the Fe—Ni alloy metal layer 5 and the conductor 4. Moreover, after plating, the heat treatment allows part of the Fe—Ni alloy metal layer to recrystallize, leading to a stronger bond. That is, the crystals formed after plating exhibit anisotropy depending on the crystal growth direction. However, heat treatment generates new crystal grains with different orientations, resulting in an extremely strong bond between the Fe—Ni alloy metal layer 5 and the conductor 4.

As shown in FIG. 2(C), when coating the Fe—Ni alloy metal layer 5 on the back-surface side of the semiconductor chip 2, it is preferable to perform the coating through plating before dicing the wafer. In other words, by conducting the plating process on the wafer as a whole and then performing dicing, it becomes possible to efficiently produce semiconductor chips 2 with the Fe—Ni alloy metal layer 5 formed on the backside.

In FIG. 2, regarding the front surface (upper surface side) of the semiconductor chip 2, wire bonding is used to connect the front-surface electrode to the lead 3b. Since the wire 8, being the conductor, is flexible, no stress is applied between the wire 8 and the lead 3b. However, due to the difference in thermal expansion coefficients between the material of the wire 8 and the semiconductor chip 2, thermal stress may cause damage to the semiconductor chip 2 in the wire bonding area, albeit in a small region.

The conducting material of the wire 8 is generally aluminum, gold, or copper. In the case of ball bonding, the bond part of material of the wire 8 is melted and the bonded area is relatively small, so thermal stress rarely becomes a problem. However, in the case of power devices, wedge bonding is used. Here, the diameter of the wire 8 ranges from approximately 50 μm to 500 μm, and it is work-hardened during bonding, preventing the bonded part of material of the wire 8 from undergoing plastic deformation during thermal cycling, thereby applying stress to the semiconductor chip 2. FIG. 3 illustrates the connecting area of the semiconductor chip in wire bonding. FIG. 3(A) shows the conventional wedge bonding on an Al electrode 2b, while FIG. 3(B) illustrates wedge bonding on an Al/Fe—Ni/Au electrode in the present embodiment. As described above, in the conventional case shown in FIG. 3(A), plastic deformation of the wire 8 material does not progress sufficiently during thermal cycling, resulting in stress being applied to the semiconductor chip 2. In contrast, in the present embodiment, as shown in FIG. 3(B), by coating an Fe—Ni alloy metal layer 5 with a lower thermal expansion coefficient than the material of the wire 8 on the surface of the Al electrode 2b of the semiconductor chip 2, the aforementioned issue can be resolved.

In this case, the composition of the Fe—Ni alloy metal layer 5 is similar to the above, with a Ni weight percentage concentration in the range of approximately 30% to 45%. The thickness is set to 2 μm or more, preferably 5 μm or more and up to 20 μm. The Fe—Ni alloy metal layer 5 can be coated by physical vapor deposition or plating. Typically, the electrode material is about 1-4 μm thick aluminum. However, if direct coating of the Fe—Ni alloy metal is not possible, pretreatments such as zincate treatment or Ni plating may be performed. Furthermore, as shown in FIG. 3(B), it is desirable to coat a plating layer 2c (e.g., Au, Ag, or Al) on top of the Fe—Ni alloy metal layer 5 to prevent oxidation of the Fe—Ni alloy metal layer 5.

Next, the case of a flip-chip structure will be explained. FIG. 4 shows the structure of a semiconductor device using flip-chip connections according to the present embodiment. FIG. 4 illustrates the flip-chip structure in semiconductor mounting, where the circuit surface of the semiconductor chip 2 is connected facing the substrate conductor electrode 4a (e.g., a Cu electrode:) of the substrate 9. The substrate electrode 4a and the semiconductor chip 2 are connected via solder balls (solder 7) and joined by melting the solder 7. Traditionally, ceramic substrates have been used for substrate 9 to reduce the thermal expansion difference with the semiconductor chip 2. However, the current trend has shifted toward the widespread use of organic substrates, which have a higher thermal expansion coefficient. While practical application has been achieved by fixing the semiconductor chip 2 to the substrate 9 with underfill, an insulating resin, to suppress deformation caused by thermal expansion differences, deformation due to thermal expansion differences becomes significant. for large-sized semiconductor chips or high-power applications.

To address this issue, adopting the structure shown in FIG. 4 makes it possible to suppress deformation caused by thermal expansion differences. In FIG. 4(A), an Fe—Ni alloy metal layer 5 is coated on the connecting surface of the semiconductor chip 2 and connected to the conductor 4 (substrate electrode 4a of substrate 9) via solder 7. In FIG. 4(B), the Fe—Ni alloy metal layer 5 is coated on the surface of the conductor 4 (substrate electrode 4a of substrate 9) and connected to the connecting surface of the semiconductor chip 2 via solder 7. In both cases, a heat sink 21 is provided above the semiconductor chip 2 for heat dissipation. Since the Fe—Ni alloy metal layer 5 is formed between the semiconductor chip 2 and the substrate electrode 4a in FIG. 4, it is possible to alleviate stress caused by thermal expansion differences. This structure, as shown in FIG. 4, is particularly effective for power devices where the electrode area is large. For the structure in FIG. 4(A), the Fe—Ni alloy metal layer 5 is formed by physical vapor deposition or plating. For the structure in FIG. 4(B), methods such as cladding, physical vapor deposition, plating, thermal spraying, or sintering can be used.

FIG. 5 shows the flip-chip connection structure with a Cu pillar in the semiconductor device according to the present embodiment. In FIG. 5, a Cu pillar 10, which is the conductor 4, is formed on the electrode side of the semiconductor chip 2 and connected to the substrate electrode 4a via solder 7. Between the semiconductor chip 2 and the Cu pillar 10, an Fe—Ni alloy metal layer 5 is formed. This configuration alleviates the thermal expansion difference between the Cu pillar 10 and the semiconductor chip 2, enabling the same stress relief from thermal expansion differences as described above. The Fe—Ni alloy metal layer 5 in FIG. 5 is formed by physical vapor deposition or plating.

Next, the structure for power device mounting is described. FIG. 6 illustrates the structure of a power device in the semiconductor device according to the present embodiment. In power device mounting, heat dissipation structure is critical in addition to supporting high power output. In FIG. 6, ceramics, which have relatively low thermal expansion, are often used as the insulating substrate 61. However, the thermal expansion difference between the copper conductor (Cu wiring 62, and heat-dissipation substrate 63) carrying large currents and the semiconductor chip 2 may cause issues. To address this, the Fe—Ni alloy metal layer 5 is coated on the back-surface side of the semiconductor chip 2, as shown in FIG. 6. This configuration, as with the previous cases, allows for the mitigation of stress caused by thermal expansion differences.

As shown in FIG. 6, it is also desirable to coat the Fe—Ni alloy metal layer 5 on the connecting area of the semiconductor chip 2 in wire bonding, as described in FIG. 3. The Fe—Ni alloy metal layer 5 in FIG. 6 is formed by physical vapor deposition or plating.

FIG. 7 illustrates an example of a lead-connected power device structure. The structure shown in FIG. 7 uses leads 3b and features a configuration where the lead 3b, which has expected heat dissipation properties, is directly connected to the front-surface of the semiconductor chip 2. Fe—Ni alloy metal layers 5 are formed on the front-surface of the semiconductor chip 2 and between the back-surface of the semiconductor chip 2 and the copper conductor (such as lead 3b and the heat-dissipation substrate 63), and each is connected via solder 7. FIG. 8 illustrates an example of a double-sided heat dissipation power device structure. In these structures, when the electrode on the surface of the semiconductor chip 2 is directly connected to the copper conductor (e.g., Cu wiring 62), the difference in thermal expansion coefficients between these materials becomes an issue.

As shown in FIGS. 7 and 8, inserting the Fe—Ni alloy metal layer 5 between the semiconductor chip 2 and the copper wiring alleviates the stress on the semiconductor chip 2. Particularly, for the double-sided heat dissipation mounting structure shown in FIG. 8, it is preferable to form the Fe—Ni alloy metal layer 5 on both the front-surface and back-surface electrodes of the semiconductor chip 2. In FIGS. 7 and 8, the Fe—Ni alloy metal layer 5 is formed by physical vapor deposition or plating.

Next, the Nickel Micro Plating Bonding (NMPB) structure developed by the inventors will be explained. For power devices, as shown in FIG. 6 to 8, connections are often made using solder 7, or for high-heat-resistance devices, materials such as Ag sintered materials are commonly used. However, solder 7 has the issue of a low melting point, while Ag sintered materials face problems such as Ag migration and high costs. To address these issues, the inventors developed a nickel micro plating bonding technology, where the semiconductor chip 2 and the lead 3b or substrate 9 (copper substrate) are connected via Ni plating through the edge (see, for example, Patent Document 1, International Publication WO2017/154893). This technology involves forming a tapered edge portion of the conductor lead 3a, which comes into dot-like or line-like contact, or close proximity, with the semiconductor chip 2. The distance between the semiconductor chip 2 and the tapered conductor lead 3a gradually increases from the point of contact or proximity outward. Ni plating is applied in this gap, where the Ni plating solution is filled, thereby connecting the semiconductor chip 2 and the conductor lead 3a. The Ni plating provides a highly robust connection that does not fracture under thermal stress, although thermal stress on the semiconductor chip 2 can occasionally cause leakage on the chip side.

FIG. 9 provides an example of the NMPB structure in the semiconductor device according to the present embodiment. FIG. 9(A) shows the structure where Ni is used for plating bonding, and FIG. 9(B) shows the structure where Fe—Ni alloy metal is used for plating bonding. In FIG. 9(A), the Fe—Ni alloy metal layer 5 is formed on the connecting surface of the semiconductor chip 2, and the Fe—Ni alloy metal layer 5 and the edge of lead 3b are bonded using Ni plating 91. Alternatively, Ni plating 91 can be replaced with Fe—Ni alloy plating. The Fe—Ni alloy metal layer 5 in this case is formed by physical vapor deposition or plating. In FIG. 9(B), Fe—Ni alloy plating is applied with the electrode of the semiconductor chip 2 and the edge of lead 3b in contact, forming the Fe—Ni alloy metal layer 5 and connecting the semiconductor chip 2 and lead 3b via the edge. In both structures, the formation of the Fe—Ni alloy metal layer 5 between the semiconductor chip 2 and the copper electrode relieves stress on the semiconductor chip 2 caused by thermal expansion differences.

As shown in FIG. 9, when performing Ni plating or Fe—Ni alloy plating as described above, it is desirable to carry out heat treatment at approximately 200° C. to 350° C. after plating. This optimizes the composition and rearranges the atoms, forming a diffusion layer at the interface between the plated metal and conductor 4, thereby achieving a robust bond. Additionally, heat treatment following the plating process causes partial recrystallization of the Fe—Ni alloy metal layer, further strengthening the connection.

At the interface between the plated metal and conductor 4, a strong bond is achieved through diffusion layers or recrystallization. Moreover, similar phenomena occur at the interface where the opposing plating growth surfaces collide (interface 92 shown in FIG. 9), further enhancing the strength of the bond formed by plating.

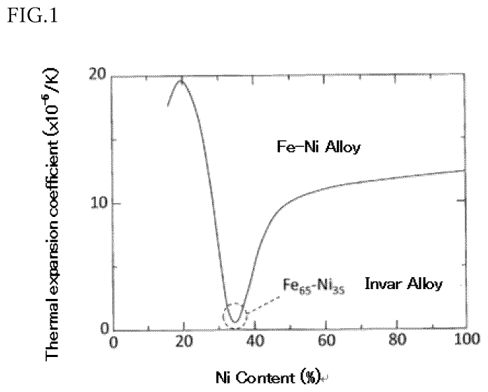

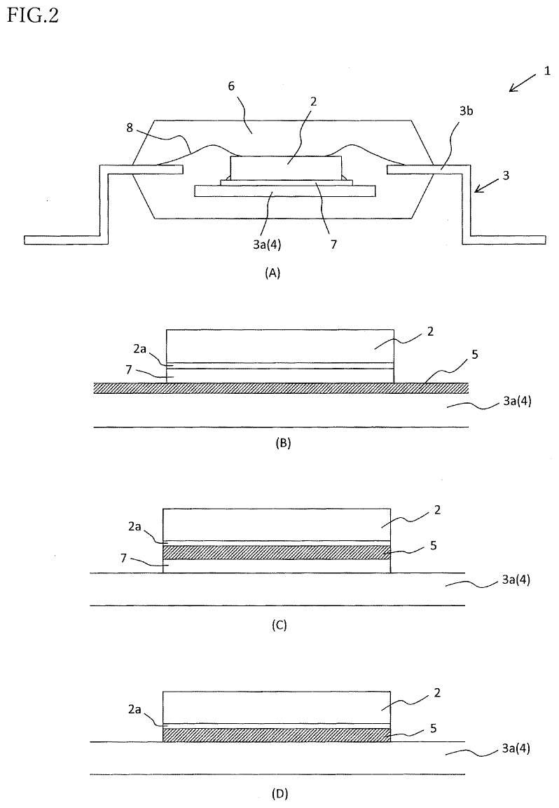

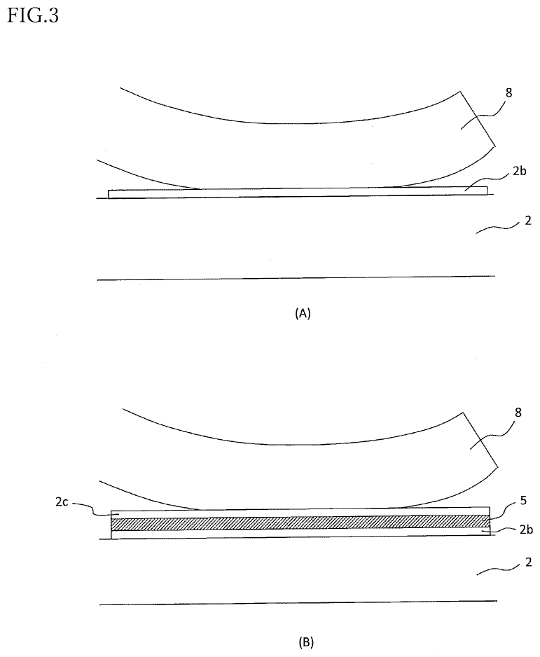

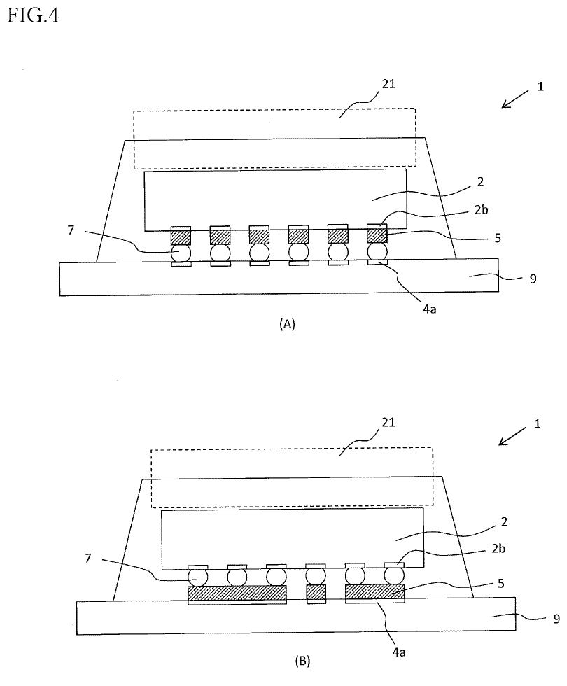

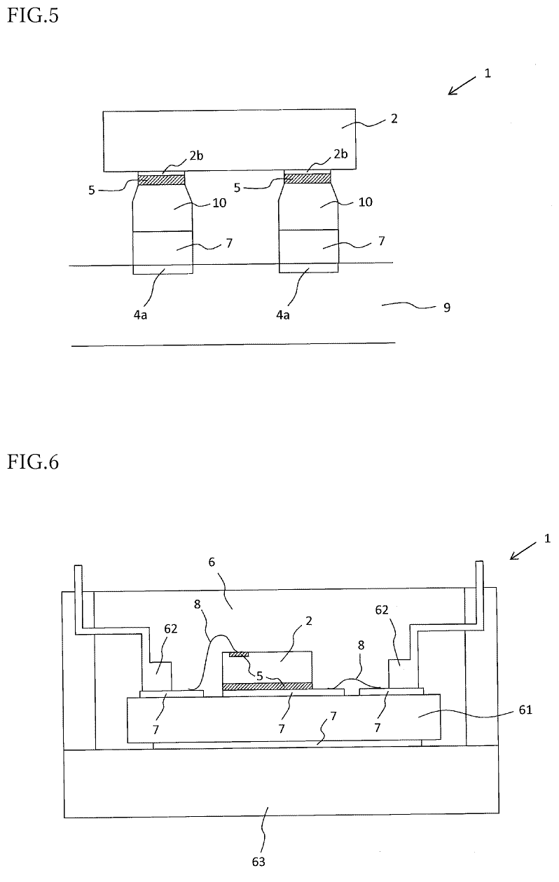

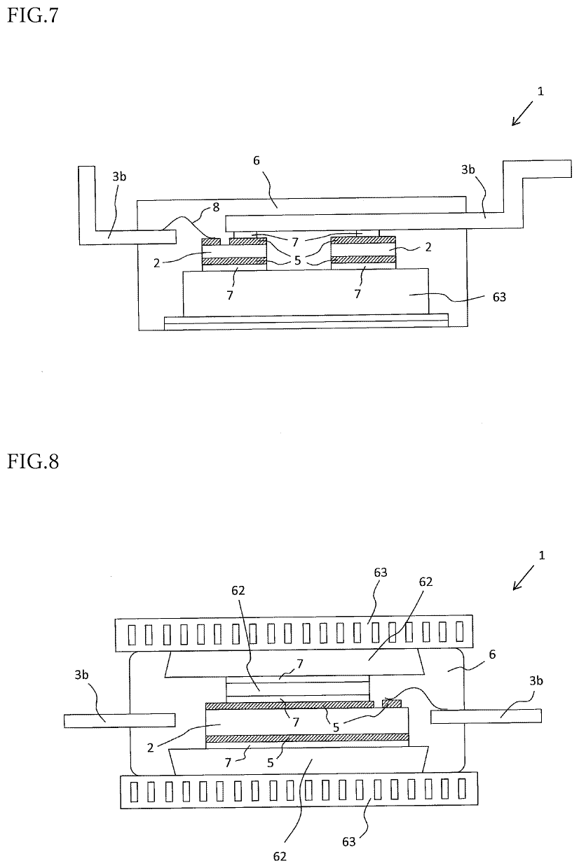

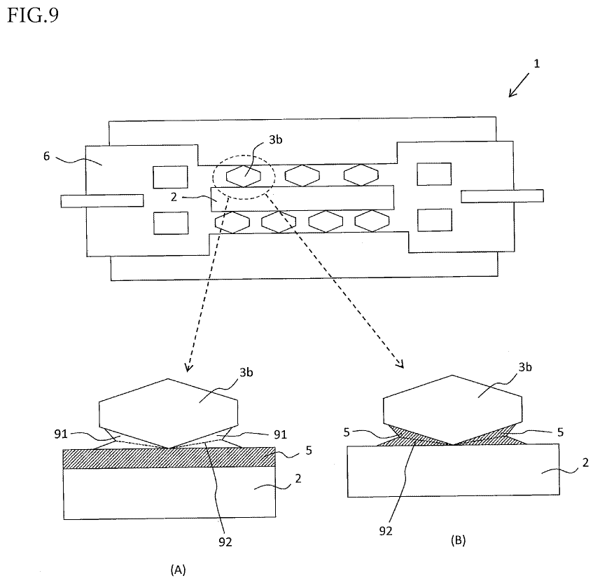

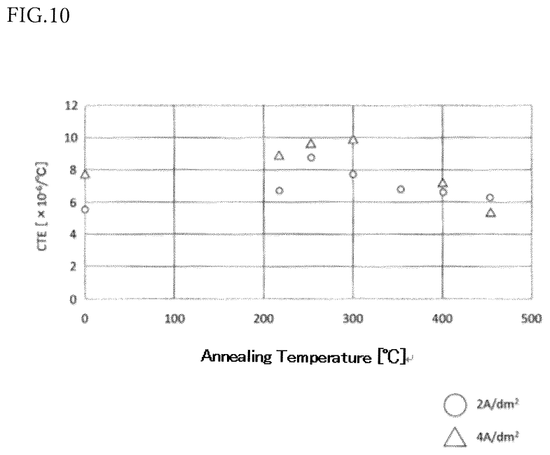

The inventors conducted experiments to analyze the effects of heat treatment on the Fe—Ni alloy metal layer 5 after plating formation, as illustrated in FIG. 10. In these experiments, the current density during plating was set to 2 A/dm² or 4 A/dm², and the Fe—Ni alloy metal layer 5 was plated to have a composition of Fe-(33-44)Ni (wt %). Subsequent heat treatments were performed at 0° C. (untreated), 220° C., 250° C., 300° C., 350° C., 400° C., and 450° C. The linear expansion coefficients of the Fe—Ni alloy metal layer 5 subjected to each temperature were measured during temperature changes between 50° C. and 250° C.

As shown in the measurement results in FIG. 10, the linear expansion coefficient varies depending on the heat treatment temperature. This indicates that the linear expansion coefficient can be adjusted through post-plating heat treatment according to the operating environment or application of the semiconductor device 1. Specifically, by performing heat treatment at a temperature higher than the operating temperature of the semiconductor device 1, large variations in the linear expansion coefficient due to temperature changes can be prevented, enabling operation at a constant linear expansion coefficient.

Thus, in the semiconductor device according to the present embodiment, the Fe—Ni alloy metal layer 5 is coated directly or indirectly onto the front-surface electrode or back-surface electrode of the semiconductor chip 2, and the semiconductor chip is connected to the conductor through the Fe—Ni alloy metal layer 5. This configuration alleviates the stress caused by the thermal expansion difference between the semiconductor chip 2 and the conductor, thereby preventing damage to the semiconductor chip 2.

Moreover, by setting the Ni weight percentage in the Fe—Ni alloy metal layer within the range of 30% to 45% and/or the thickness of the Fe—Ni alloy metal layer between 2 μm and 20 μm, it becomes possible to minimize the thermal expansion coefficient. As a result, the stress on the semiconductor chip can be reduced to a minimum, thereby preventing damage to the semiconductor chip 2.

Furthermore, forming the Fe—Ni alloy metal layer 5 through plating enables it to be coated directly to the semiconductor chip 2. Compared to sputtering, plating allows for greater thickness, which ensures sufficient resistance to thermal expansion and enables robust layer formation.

### REFERENCE SIGNS LIST

1: Semiconductor device
2: Semiconductor chip
2a: Ti/Ni/Au film
2b: Al electrode
2c: Plating layer
3: Lead frame
3a: Die pad
3b: Conductor lead
4: Conductor
4a: Substrate electrode
5: Fe—Ni alloy metal layer
6: Resin
7: Solder
8: Wire
9: Substrate
10: Cu pillar
21: Heat sink
61: Insulating substrate
62: Copper wiring
63: Heat-dissipating substrate
91: Ni plating
92: Interface

1. A semiconductor device, comprising:
a semiconductor element; and
a conductor,
wherein an Fe—Ni alloy metal layer is coated directly or indirectly onto a front-surface electrode and/or a back-surface electrode of the semiconductor element, and the semiconductor element is connected to the conductor through the Fe—Ni alloy metal layer.

2. The semiconductor device according to claim 1, wherein an Ni content in the Fe—Ni alloy metal layer is in a range of 30% to 45% by weight.

3. The semiconductor device according to claim 1, wherein a thickness of the Fe—Ni alloy metal layer is in a range of 1 μm to 5 mm.

4. The semiconductor device according to claim 1, wherein the Fe—Ni alloy metal layer is formed by plating.

5. The semiconductor device according to claim 4, wherein an electrode surface of the front-surface electrode or back-surface electrode in the semiconductor element is in contact with or in close proximity to the conductor in a dot-like or line-like manner at a connecting interface, a distance between the electrode surface and the conductor gradually increases from a point of contact or proximity outward, and a gap between the electrode surface and the conductor is filled with Fe—Ni alloy metal to form the Fe—Ni alloy metal layer.

6. The semiconductor device according to claim 4, wherein the Fe—Ni alloy metal layer is formed by way of heat-treating a Fe—Ni plated metal, thereby forming a diffusion layer at an interface between the conductor and the Fe—Ni plated metal, or recrystallizing a part of the Fe—Ni plated metal.

7. The semiconductor device according to claim 1, wherein the Fe—Ni alloy metal layer is formed by way of sintering a powder containing nano-sized metal particles and Fe—Ni alloy particles.

8. The semiconductor device according to claim 7, wherein the powder contains micron-sized Al particles.

9. A method of connecting a semiconductor element and a conductor, the method comprising:
bringing an electrode surface of a front-surface electrode or back-surface electrode in the semiconductor element into contact with, or in close proximity to, the conductor in a dot-like or line-like manner at a connecting interface;
filling Fe—Ni plating metal into a gap to form a plating connection, wherein the gap between the electrode surface and the conductor gradually increases outward from points of contact or proximity; and
heat-treating the plating connection.

10. A connecting material comprising:
a powder including nano-sized metal particles and Fe—Ni alloy particles,
wherein the powder is formed into an Fe—Ni alloy metal layer applied directly or indirectly onto a front-surface electrode and/or a back-surface electrode of a semiconductor element.

11. The semiconductor device according to claim 2, wherein a thickness of the Fe—Ni alloy metal layer is in a range of 1 μm to 5 mm.

12. The semiconductor device according to claim 2, wherein the Fe—Ni alloy metal layer is formed by plating.

13. The semiconductor device according to claim 12, wherein an electrode surface of the front-surface electrode or back-surface electrode in the semiconductor element is in contact with or in close proximity to the conductor in a dot-like or line-like manner at a connecting interface, a distance between the electrode surface and the conductor gradually increases from a point of contact or proximity outward, and a gap between the electrode surface and the conductor is filled with Fe—Ni alloy metal to form the Fe—Ni alloy metal layer.

14. The semiconductor device according to claim 12, wherein the Fe—Ni alloy metal layer is formed by way of heat-treating a Fe—Ni plated metal, thereby forming a diffusion layer at an interface between the conductor and the Fe—Ni plated metal, or recrystallizing a part of the Fe—Ni plated metal.

15. The semiconductor device according to claim 2, wherein the Fe—Ni alloy metal layer is formed by way of sintering a powder containing nano-sized metal particles and Fe—Ni alloy particles.

16. The semiconductor device according to claim 15, wherein the powder contains micron-sized Al particles.

17. The method of claim 9, wherein an Ni content in the Fe—Ni plating metal is in a range of 30% to 45% by weight.

18. A semiconductor device comprising the connecting material of claim 10 positioned between the semiconductor element and a conductor.
